(19) United States
(12) Patent Application Publication
(10) Pub. No.: US 2020/0106394 A1
(43) Pub. Date: Apr. 2, 2020

(54) RECONFIGURABLE BROADBAND AND NOISE CANCELLATION LOW NOISE AMPLIFIER (LNA) WITH INTRA-CARRIER AGGREGATION (CA) CAPABILITY

(71) Applicant: QUALCOMM Incorporated, San Diego, CA (US)

(72) Inventors: Prakash THOPPAY EGAMBARAM, San Diego, CA (US); Ojas CHOKSI, San Diego, CA (US)

(21) Appl. No.: 16/145,525

(22) Filed: Sep. 28, 2018

(51) Int. Cl. H03F 1/26; H03F 3/195

(52) U.S. Cl. CPC H03F 1/26; H03F 2200/396; H03F 2200/294; H03F 3/195

(57) ABSTRACT

Techniques for a reconfigurable broadband and noise cancellation LNA architecture with intra-CA capabilities are provided. An example of a device according the disclosure includes a resistive matching stage configured to receive a communication signal, a first cancellation path configured to receive the communication signal, the first cancellation path operably coupled to the resistive matching stage and a first load, and a first current combiner circuit operably coupled to the resistive matching stage and the first load, the first current combiner circuit being configured to control a phase of a current of the communication signal received from the resistive matching stage.

### BACKGROUND

In a radio frequency (RF) transceiver, a communication signal is typically received and down converted by receive circuitry, sometimes referred to as a receive chain. A receive chain typically includes a receive filter, a low noise amplifier (LNA), a mixer, a local oscillator (LO), a voltage controlled oscillator (VCO), a baseband filter, and other components, to recover the information contained in the communication signal. The transceiver may also include circuitry that enables the transmission of a communication signal to a receiver in another transceiver. The transceiver may be able to operate over multiple frequency ranges, typically referred to a frequency bands. Moreover, a single transceiver may be configured to operate using multiple carrier signals that may occur in the same frequency band, but that may not overlap in actual frequency, an arrangement referred to as non-contiguous carriers.

In an example, a single transmitter or receiver may be configured to operate using multiple transmit frequencies and/or multiple receive frequencies. For a receiver to be able to simultaneously receive two or more receive signals, the concurrent operation of two or more receive paths is required. Such systems are sometimes referred to as Carrier Aggregation (CA) systems. The term carrier aggregation may refer to systems that include inter-band carrier aggregation and intra-band carrier aggregation. Intra-band carrier aggregation refers to the processing of two separate and non-contiguous carrier signals that occur in the same communication band. To accommodate the broad operating ranges and bandwidths associated with carrier aggregation systems, an RF transceiver may require several switchable active and passive devices. A broadband LNA, for example, may require one or more variable capacitors to support impedance matching across the required frequencies. Such matching circuits may generate signal noise within the LNA and may degrade the performance of the LNA.

### SUMMARY

An example of a noise cancellation circuit according to the disclosure includes a first transconductance stage operably coupled to a radio-frequency input, a resistive matching circuit including a second transconductance stage operably coupled to the radio-frequency input, a first resistance element having a first terminal operably coupled to the radio-frequency input and a second terminal operably coupled to an output of the second transconductance stage, and a voltage-to-current converter circuit having an input terminal operably coupled to the output of the second transconductance stage, a second resistance element having a first terminal operably coupled to an output of the voltage-to-current converter circuit and a second terminal operably coupled to an output of the first transconductance stage, and a capacitance element having a first terminal operably coupled to the output of the voltage-to-current converter circuit and a second terminal operably coupled to the output of the first transconductance stage.

Implementations of such a noise cancellation circuit may include one or more of the following features. The first transconductance stage may include a capacitor coupled between the second terminals of the second resistance element and capacitance elements and one or more transconductance elements of the first transconductance stage. The second transconductance stage may include a first transistor having a gate operably coupled to the radio-frequency input, and a second transistor having a gate operably coupled to the radio-frequency input, wherein the second terminal of the first resistance element is operably coupled to a drain of the first transistor and the second transistor, such that the first transconductance stage includes a third transistor having a gate operably coupled to the radio-frequency input, and a fourth transistor having a gate operably coupled to the radio-frequency input, voltage-to-current converter circuit includes a fifth transistor, wherein the gate of the fifth transistor is operably coupled to the drain of the first transistor and a drain of second transistor. The first resistance element may be a first variable resistance element. The second resistance element may be a second variable resistance element or the capacitance element is a variable capacitance element. The first transistor may be a p-type metal oxide semiconductor (PMOS) transistor and the second transistor may be an n-type metal oxide semiconductor (NMOS) transistor, or the first transistor may be an NMOS transistor and the second transistor may b a PMOS transistor. The third transistor may be a p-type metal oxide semiconductor (PMOS) transistor and the fourth transistor may be an n-type metal oxide semiconductor (NMOS) transistor, or the third transistor may be an NMOS transistor and the fourth transistor may be a PMOS transistor. The capacitance element may be a first capacitance element, the first transconductance stage may further include a sixth transistor having a gate operably coupled to the radio-frequency input, a seventh transistor having a gate operably coupled to the radio-frequency input, such that the voltage-to-current converter circuit includes an eighth transistor having a gate operably coupled to the drain of the first transistor and the drain of the second transistor, a third resistance element having a first terminal operably coupled to a source of the eighth transistor and a second terminal operably coupled to a drain of the sixth transistor and to a drain of the seventh transistor via a capacitor, and a second capacitance element having a first terminal operably coupled to the source of the eighth transistor and a second terminal operably coupled to the drain of the sixth transistor and the drain of the seventh transistor via the capacitor. A primary component carrier processing circuit may be coupled to a first node coupled to the drain of the third transistor, the drain of the fourth transistor, and the second terminals of each of the second resistance element and the first capacitance element, and a secondary component carrier processing circuit may be coupled to a second node coupled to the drain of the sixth transistor, the drain of the seventh transistor, and the second terminals of each of the third resistance element and the second capacitance element. A first switch having a first terminal may be operably connected to the drain of the third transistor and the drain of the fourth transistor, the first switch may have a second terminal operably coupled to the drain of the sixth transistor and the drain of the seventh transistor, and a second switch in parallel with the first switch may have a first terminal operably connected to the drain of the third transistor and the drain of the fourth transistor, the first switch may have a second terminal operably coupled to the drain of the sixth transistor and the drain of the seventh transistor. Each of the first transconductance stage and the second transconductance stage may include at least one of an inverter, a transistor, or a cascode. A value of the second resistance element and a value of the capacitance element may be based on a frequency of a signal at the radio-frequency input. A frequency of a signal at the radio-frequency input may be in a range of 600 MHz to 3.8 GHz. The noise cancellation circuit may form at least a portion of a low noise amplifier (LNA) circuit in a receive path of a transceiver. An output of the noise cancellation circuit may be operably connected to a node operably coupled to the output of the second transconductance stage and the second terminals of each of the second resistance element and the capacitance element. The radio-frequency input may include a primary component carrier and a secondary component carrier in a carrier aggregation application. The primary component carrier and the secondary component carrier may be based on a non-contiguous carrier aggregation application.

An example of a device according the disclosure includes a resistive matching stage configured to receive a communication signal, a first cancellation path configured to receive the communication signal, the first cancellation path operably coupled to the resistive matching stage and a first load, and a first current combiner circuit operably coupled to the resistive matching stage and the first load, the first current combiner circuit being configured to control a phase of a current of the communication signal received from the resistive matching stage.

Implementations of such a device may include one or more of the following features. The first current combiner circuit may be controlled to cancel noise through the first cancellation path from the resistive matching stage. Noise from the resistive matching stage through the first cancellation path may be combined out-of-phase with noise through the resistive matching stage. The resistive matching stage may include a first variable resistance element operably coupled to a drain of a first transistor and a drain of a second transistor, and the first cancellation path may include a third transistor and a fourth transistor, a gate of the third transistor may be operably coupled to a gate of the first transistor in the resistive matching stage, and a gate of the fourth transistor may be operably coupled to a gate of the second transistor in the resistive matching stage. The first current combiner circuit may include a fifth transistor and a filter network, a gate of the fifth transistor may be operably coupled to the first variable resistance element in the resistive matching stage, and a source of the fifth transistor may be operably coupled to a second variable resistance element and a variable capacitance element in the filter network. A value of the second variable resistance element and a value of the variable capacitance element may be based on a frequency of the communication signal. The communication signal may include a primary component carrier and a secondary component carrier in a carrier aggregation application. A second cancellation path may be operably coupled to the resistive matching stage and a second load, and a second current combiner circuit operably coupled to the resistive matching stage and the second load. A second cancellation path, such that the second cancellation path may include a first secondary component carrier transistor and a second secondary component carrier transistor, a gate of the first secondary component carrier transistor may be operably coupled to a gate of the first transistor in the resistive matching stage, and a gate of the second secondary component carrier transistor may be operably coupled to a gate of the second transistor in the resistive matching stage, a second current combiner circuit, such that the second current combiner circuit may include a second current combiner transistor and a second current combiner filter network, a gate of the second current combiner transistor may be operably coupled to the first variable resistance element in the resistive matching stage, and a source of the second transistor may be operably coupled to the second current combiner filter network, and the second current combiner filter network may be operably coupled to a second load. A plurality of switches may be configured to enable a first current flow from the first cancellation path and the first current combiner circuit to the first load, or to enable a second current flow from the second cancellation path and the second current combiner circuit to the second load. The communication signal may include a primary component carrier and a secondary component carrier in an intra-band carrier aggregation application. The device may be at least a portion of a low noise amplifier (LNA) circuit in a receive path of a transceiver. The resistive elements and capacitive elements may be respective variable resistive elements and variable capacitive elements.

An example of a method for providing noise cancellation according to the disclosure includes performing impedance matching of a radio signal input with a resistive matching component, providing the radio signal input to one or more current combiner circuits, cancelling noise generated in the resistive matching component with a cancellation path, and providing an output of the one or more current combiner circuits and an output of the cancellation path to a load.

Implementations of such a method may include one or more of the following features. A resistance value for at least one resistor and a capacitance value for at least one capacitor may be set in the one or more current combiner circuits, such that the resistance value and the capacitance value are based on a frequency of the radio signal input. The radio signal input may include a primary component carrier and a secondary component carrier.

An example device according to the disclosure includes a resistive matching means configured to receive communication signal, means for canceling noise generated in the resistive matching means, and means for controlling a phase of a current of the communication signal received from the resistive matching means.

### BRIEF DESCRIPTION OF THE DRAWINGS

FIG. 1 is a diagram showing a wireless device communicating with a wireless communication system.

FIG. 2A is a graphical diagram showing an example of contiguous intra-band carrier-aggregation (CA).

FIG. 2B is a graphical diagram showing an example of non-contiguous intra-band CA.

FIG. 2C is a graphical diagram showing an example of inter-band CA in the same band group.

FIG. 2D is a graphical diagram showing an example of inter-band CA in different band groups.

FIG. 3 is an example of a block diagram of a wireless device in which a reconfigurable broadband and noise cancellation LNA with intra-carrier aggregation capability may be implemented.

FIG. 4 is a block diagram showing a non-contiguous CA application with switchable LNA circuit elements.

FIG. 5A is block diagram of an example noise cancelling LNA.

FIG. 5B is a transistor level schematic diagram of an example noise cancelling LNA.

FIG. 6 is a transistor level schematic diagram of an example broadband noise cancellation architecture.

FIG. 7 is a process flow diagram for an example method of providing noise cancellation in a low noise amplifier.

### DETAILED DESCRIPTION

Techniques are discussed herein for a reconfigurable broadband and noise cancellation LNA architecture with intra-CA capabilities. For example, the LNA architecture may include a resistive matching network, a current combiner circuit and a cancellation circuit. The cancellation circuit may be configured to cancel noise generated by the resistive matching network. The current combiner circuit may be used to extend the noise cancellation by controlling the phase of a sampled output from the restive network and then injecting the phase-controlled signal into a load. The current combiner circuit may be used to control the phase of a wide range of frequencies. These techniques are examples only, and not exhaustive.

Items and/or techniques described herein may provide one or more of the following capabilities, as well as other capabilities not mentioned. A communication signal such as a radio signal may be provided to an amplifier circuit. The amplifier may include a resistive matching network, a noise cancellation circuit, and a current combiner circuit. The current combiner circuit may include one or more RC filters configured to control the phase of an output signal based on the phase of an input communication signal. Noise generated in the resistive matching network may be canceled through the noise cancellation circuit. The current combiner enables the noise cancellation circuit to operate over a wider range of frequencies. The noise cancellation circuit and current combiner module may include multiple paths to support carrier aggregation schemes. The amplifier may provide broadband noise cancellation support for frequencies in the range of 600 MHz to 3.8 GHz with intra-carrier aggregation capability. Other capabilities may be provided and not every implementation according to the disclosure must provide any, let alone all, of the capabilities discussed. Further, it may be possible for an effect noted above to be achieved by means other than that noted, and a noted item/technique may not necessarily yield the noted effect.

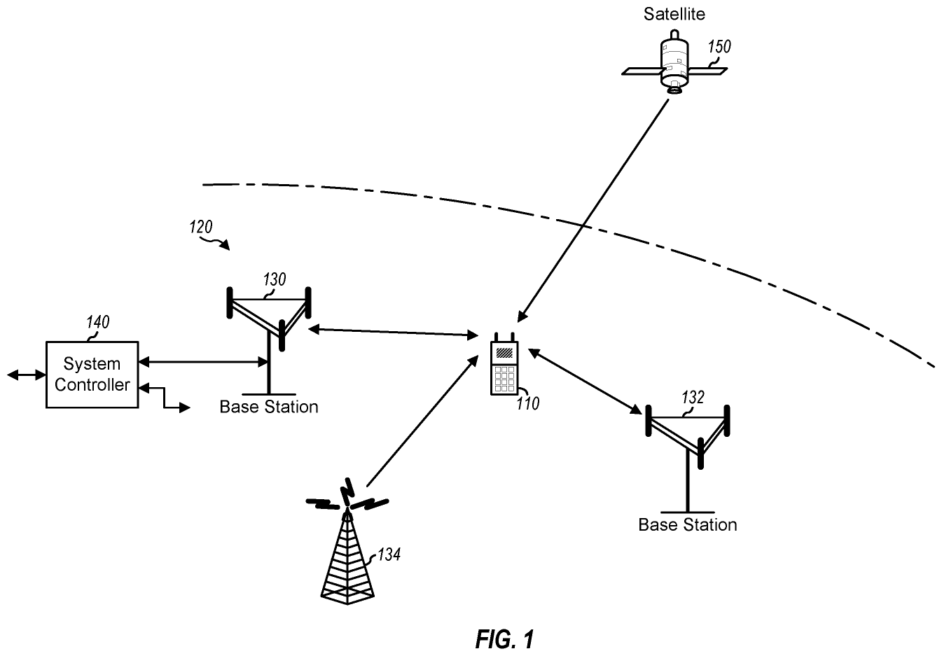

Referring to FIG. 1, a diagram including a wireless device 110 communicating with a wireless communication system 120 is shown. The wireless communication system 120 may be a Long Term Evolution (LTE) system, a Code Division Multiple Access (CDMA) system, a Global System for Mobile Communications (GSM) system, a wireless local area network (WLAN) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. In an example, the wireless communication system 120 may include the components of a Fifth Generation (5G) network comprising a Next Generation (NG) Radio Access Network (RAN) (NG-RAN) and a 5G Core Network (5GC). A 5G network may also be referred to as a New Radio (NR) network, an NG-RAN may be referred to as a 5G RAN or as an NR RAN, and 5GC may be referred to as an NG Core network (NGC). Standardization of an NG-RAN and 5GC is ongoing in 3GPP. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. The wireless device 110 may be a cellular phone, a smartphone, a tablet, a wireless modem, a personal digital assistant (PDA), a handheld device, a laptop computer, a smartbook, a netbook, a tablet, a cordless phone, a wireless local loop (WLL) station, a Bluetooth device, etc. The wireless device 110 may communicate with wireless communication system 120. The wireless device 110 may also receive signals from broadcast stations (e.g., a broadcast station 134), signals from satellites (e.g., a satellite 150) in one or more global navigation satellite systems (GNSS), etc. The wireless device 110 may support one or more radio technologies for wireless communication such as LTE, WCDMA, CDMA 1x, EVDO, TD-SCDMA, GSM, 802.11, etc.

The wireless device 110 may support carrier aggregation, which is operation on multiple carriers. Carrier aggregation may also be referred to as multi-carrier operation. The wireless device 110 may be able to operate in low-band (LB) band group covering frequencies lower than 1000 megahertz (MHz), mid-band (MB) band group covering frequencies from 1000 MHz to 2300 MHz, a high-band (HB) band group covering frequencies from 2300 MHz to 2600 MHz, and/or an ultra-high-band (UHB) covering frequencies from 2600 MHz to 3800 MHz. For example, low-band may cover 698 to 960 MHz, mid-band may cover 1475 to 2170 MHz, and high-band may cover 2300 to 2690 MHz and 3400 to 3800 MHz. Low-band, mid-band, high-band, and ultra-high-band refer to four groups of bands (or band groups), with each band group including a number of frequency bands (or simply, “bands”). Each band may cover up to 200 MHz and may include one or more carriers. Each carrier may cover up to 20 MHz in LTE. LTE Release 11 supports 35 bands, which are referred to as LTE/UMTS bands and are listed in 3GPP TS 36.101. In an embodiment, the wireless device 110 may be configured with up to five carriers in one or two bands in LTE Release 11.

In general, carrier aggregation (CA) may be categorized into two types - intra-band CA and inter-band CA. Intra-band CA refers to operation on multiple carriers within the same band. Inter-band CA refers to operation on multiple carriers in different bands.

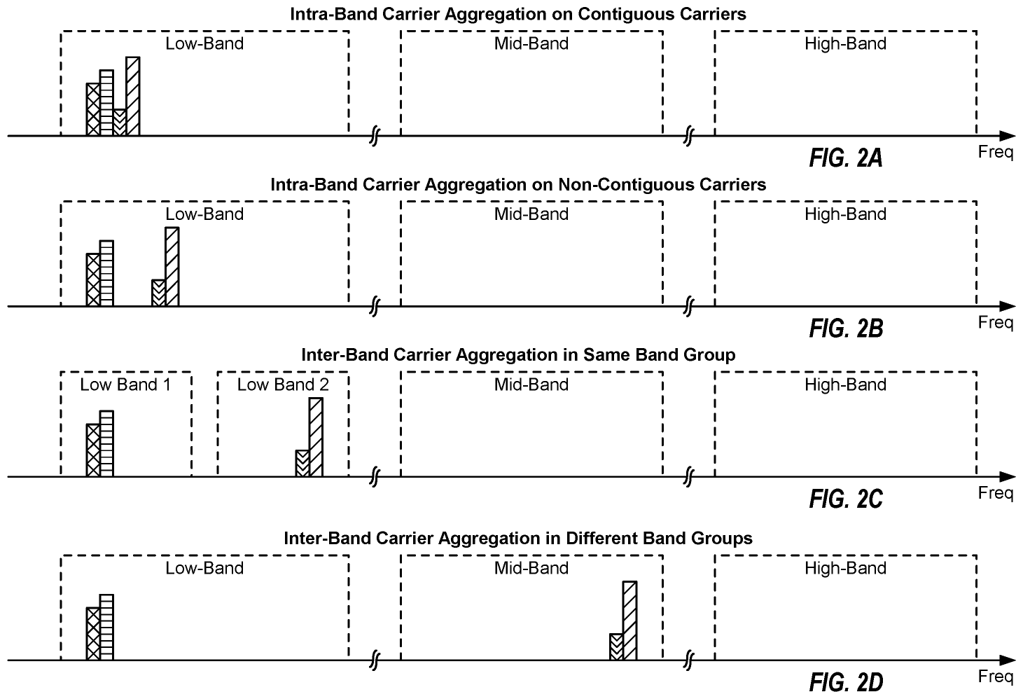

Referring to FIG. 2A, a graphical diagram of an example of contiguous intra-band carrier-aggregation (CA) is shown. In the example shown in FIG. 2A, the wireless device 110 is configured with four contiguous carriers in one band group in the low-band group. The wireless device 110 may send and/or receive transmissions on the four contiguous carriers within the same band.

Referring to FIG. 2B, a graphical diagram of an example of non-contiguous intra-band CA is shown. The wireless device 110 is configured with four non-contiguous carriers in one band group in the low-band group. The carriers may be separated by 5 MHz, 10 MHz, or some other amount. The wireless device 110 may send and/or receive transmissions on the four non-contiguous carriers within the same band.

Referring to FIG. 2C, a graphical diagram of an example of inter-band CA in the same band group is shown. The wireless device 110 is configured with four carriers in two bands in the low-band group. The wireless device 110 may send and/or receive transmissions on the four carriers in different bands in the same band group.

Referring to FIG. 2D, a graphical diagram of an example of inter-band CA in different band groups is shown. The wireless device 110 is configured with four carriers in two bands in different band groups, which include two carriers in one band in low-band and two carriers in another band group in the mid-band group. The wireless device 110 may send and/or receive transmissions on the four carriers in different bands in different band groups.

FIGS. 2A to 2D show four examples of carrier aggregation. Carrier aggregation may also be supported for other combinations of bands and band groups.

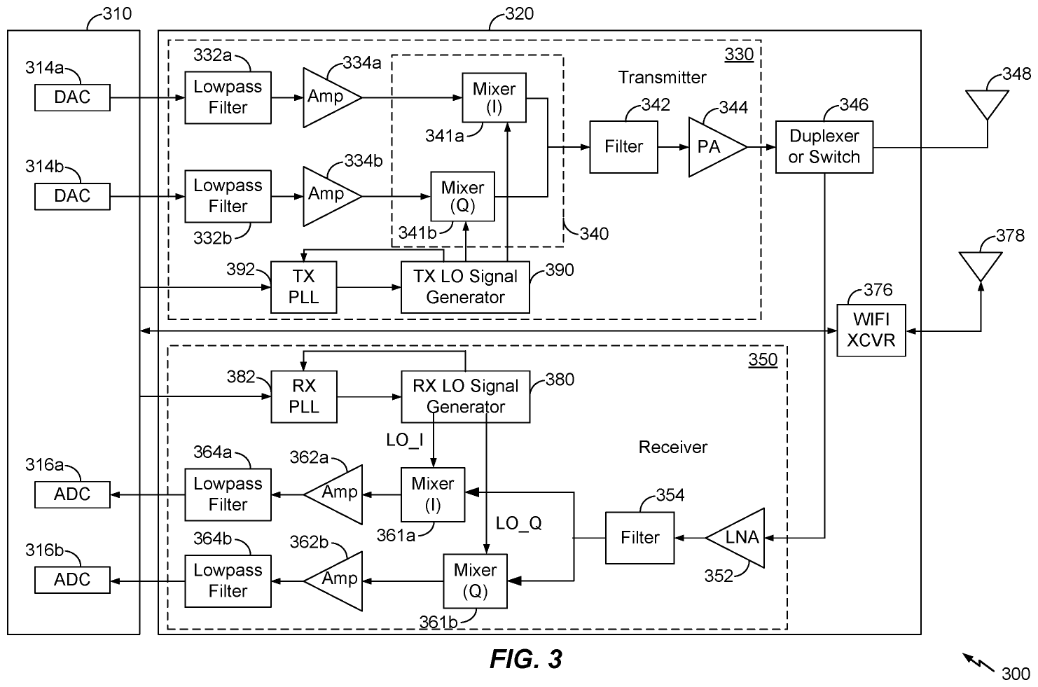

Referring to FIG. 3, an example of a block diagram of a wireless device 300 in which a reconfigurable broadband and noise cancellation LNA with intra-carrier aggregation capability may be implemented is shown. The wireless device 300 generally comprises a transceiver 320 and a data processor 310. The data processor 310 may include a memory (not shown) to store data and program codes and may generally comprise analog and digital processing elements. The transceiver 320 includes a transmitter 330 and a receiver 350 that support bi-directional communication. The wireless device 300 may include any number of transmitters and/or receivers for any number of communication systems and frequency bands. All or a portion of the transceiver 320 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the example shown in FIG. 3, transmitter 330 and receiver 350 are implemented with the direct-conversion architecture.

In the transmit path, the data processor 310 processes data to be transmitted and provides in-phase (I) and quadrature (Q) analog output signals to the transmitter 330. The data processor 310 may include one or more digital-to-analog-converters (DAC's) 314a and 314b for converting digital signals generated by the data processor 310 into the I and Q analog output signals, e.g., I and Q output currents, for further processing.

Within the transmitter 330, one or more lowpass filters 332a and 332b filter the I and Q analog transmit signals, respectively, to remove undesired images caused by the prior digital-to-analog conversion. Amplifiers (Amp) 334a and 334b amplify the signals from lowpass filters 332a and 332b, respectively, and provide I and Q baseband signals. An upconverter 340 includes the mixers 341a and 341b and is configured to upconvert the I and Q baseband signals with I and Q transmit (TX) local oscillator (LO) signals from a TX LO signal generator 390 and provides an upconverted signal. A filter 342 filters the upconverted signal to remove undesired images caused by the frequency up-conversion as well as noise in a receive frequency band. A power amplifier (PA) 344 amplifies the signal from filter 342 to obtain the desired output power level and provides a transmit RF signal. The transmit RF signal is routed through a duplexer or switch 346 and transmitted via an antenna 348.

In the receive path, one or more antennas 348 receives communication signals and provides a received RF signal, which is routed through a duplexer or a switch 346 and provided to a low noise amplifier (LNA) 352. The LNA 352 may be a reconfigurable broadband and noise cancellation LNA with intra-carrier aggregation capability as described herein. The switch 346 is designed to operate with a specific RX-to-TX duplexer frequency separation, such that RX signals are isolated from TX signals. The received RF signal is amplified by LNA 352 and filtered by a filter 354 to obtain a desired RF input signal. One or more down conversion mixers 361a and 361b are configured to mix the output of filter 354 with I and Q receive (RX) LO signals (i.e., LO_I and LO_Q) from an RX LO signal generator 380 to generate I and Q baseband signals. The I and Q baseband signals are amplified by amplifiers 362a and 362b and further filtered by lowpass filters 364a and 364b to obtain I and Q analog input signals, which are provided to data processor 310. In an example, the data processor 310 includes analog-to-digital-converters (ADC's) 316a and 316b for converting the analog input signals into digital signals to be further processed by the data processor 310.

A TX LO signal generator 390 generates the I and Q TX LO signals used for frequency up-conversion, while a RX LO signal generator 380 generates the I and Q RX LO signals used for frequency down conversion. Each LO signal is a periodic signal with a particular fundamental frequency. A phase locked loop (PLL) 392 receives timing information from data processor 310 and generates a control signal used to adjust the frequency and/or phase of the TX LO signals from LO signal generator 390. Similarly, a PLL 382 receives timing information from data processor 310 and generates a control signal used to adjust the frequency and/or phase of the RX LO signals from LO signal generator 380.

In an example, the wireless device 300 may also comprise a WIFI transceiver 376. The WIFI transceiver 376 may be coupled to an antenna 378 and to the data processor 310. The WIFI transceiver 376 may include transmit and receive circuitry configured to communicate over one or more WIFI communication bands pursuant to one or more of the IEEE 801.11 protocols. Although shown as having a separate antenna 378, the WIFI transceiver 376 may also be configured to use the antenna 348, in which case, the WIFI transceiver 376 would be coupled to the duplexer or switch 346.

The wireless device 300 may support CA and may (i) receive multiple downlink signals transmitted by one or more cells on multiple downlink carriers at different frequencies and/or (ii) transmit multiple uplink signals to one or more cells on multiple uplink carriers.

In a CA communication environment where multiple receive signals are processed simultaneously, it is possible that a receive signal on a particular receive path can couple to and impair the sensitivity of a receiver operating on a receive signal on a different receive path. Moreover, it is also possible that that a WIFI transmit or receive signal can generate signal noise and impair the sensitivity of a receiver operating on a receive signal on a different receive path.

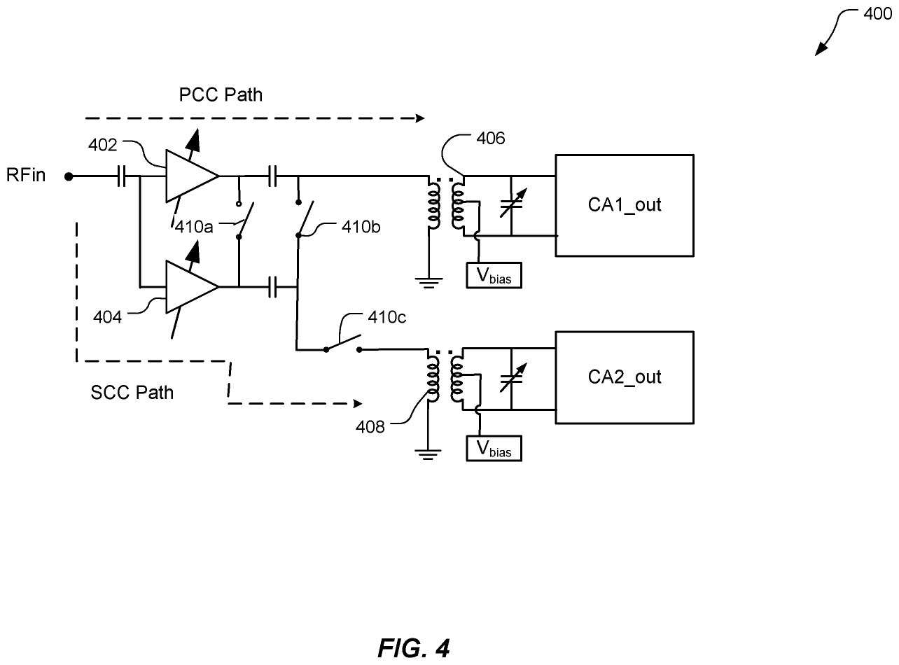

Referring to FIG. 4, a block diagram of a carrier aggregation application 400 with switchable LNA circuit elements is shown. The application 400 may be used, for example, in a Long Term Evolution (LTE) carrier aggregation application including a Primary Component Carrier (PCC) and one or more Secondary Component Carrier (SCC). In an intra-band CA configuration, a receiver may be required to operate in the Low-Band (e.g., LB, 600-900 MHz), Mid-Band (MB, 1.5-2.1 GHz), High-Band (HB, 2.1-2.6 GHz), and Ultra-High-Band (UHB, 2.6-3.8 GHz) frequencies. The application 400 includes a first LNA 402, a second LNA 404 and a plurality of switches 410a-c. Such a configuration renders the capability to move from legacy to inter/intra carrier aggregation options. The switches 410a-c are configured to direct the primary component carrier at a first frequency via the first LNA 402 to a first carrier output including a first transformer 406. The plurality of switches 410a-c may be configured to direct a secondary component carrier at a second frequency via the second LNA 404 to a second carrier output including a second transformer 408. The first and second output (e.g., CA1_out, CA2_out) are typically either single-ended or differential signals.

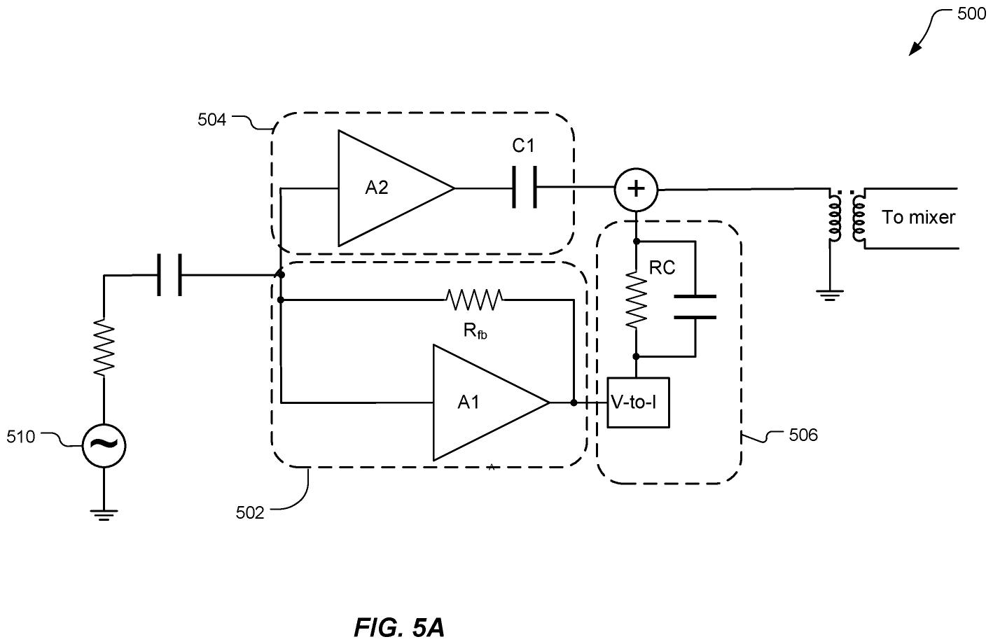

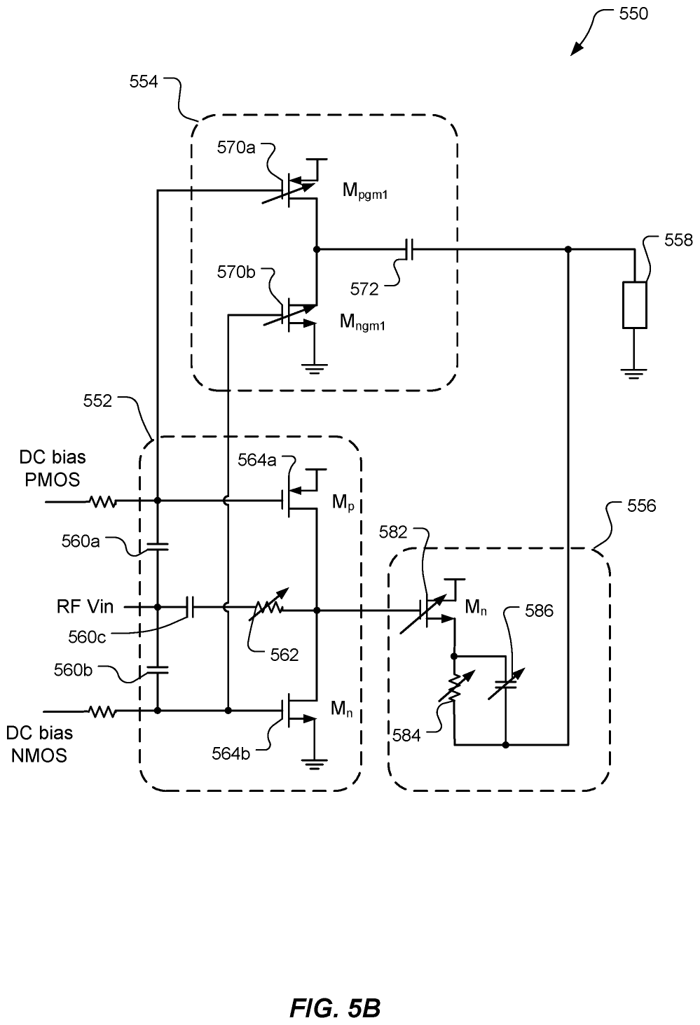

Referring to FIG. 5A, a block diagram of an example noise cancellation LNA 500 is shown. In an example, an RF Voltage input 510 is provided to a resistive matching stage 502 and transconductance stage 504. The resistive matching stage 502 may be a means for receiving a communication signal, and may include a first transconductance stage such as a first amplifier A1 and one or more feedback components such as a feedback resistor Rfb. The transconductance stage 504 may be a means for canceling noise in the resistive matching stage 502, and include a second transconductance stage such as a second amplifier A2 and a series capacitance component such as a capacitor C1. A current combiner stage 506 is configured to combine the conductance (gm) of the path through the resistive matching stage 502 with the conductance (gm) through the transconductance stage 504. The current combiner stage 506 may be means for controlling a phase of a current of a communication signal received from the resistive matching stage 502. In an example, the current combiner stage 506 may include a voltage-to-current converter (V-to-I) in series with a RC circuit. The voltage-to-current converter may be implemented in a variety of ways, for example, as a single transistor, an operational amplifier, or other voltage-to-current converter architectures. The values of the components in RC circuit act as a phase shifter to tune the phases between the output of the transconductance stage 504 and the output of the resistive matching stage 502. Moreover, while the RC components may be fixed elements, in certain implementation each of the RC components are tunable (e.g., variable).

Referring to FIG. 5B, a transistor level schematic diagram of an example noise cancelling LNA 550 is shown. The LNA 550 is configured to operate across broadband frequencies and includes a resistive matching stage 552, a transconductance stage 554 forming a cancellation path and a current combiner 556. A communication signal input such as radio-frequency input signal (RF Vin) and DC bias voltage are provided to the resistive matching stage 552. The resistive matching stage 552 includes a plurality of DC blocking capacitors 560a-c, a first variable resistance element 562, and a transconductance stage formed from a first transistor 564a, and a second transistor 564b. The first transistor 564a and the second transistor 564b are connected to form an inverter type architecture but other transconductance configurations can be likewise used. The first transistor 564a may be a p-type MOSFET, and the second transistor 564b may be a n-type MOSFET. Other devices may also be used. In an aspect, the first variable resistance element 562 is a feedback resistor connected between an output of the transconductance stage and the input. The first variable resistance element 562 may include one or more resistors coupled to the RF Vin signal (via the DC blocking capacitor 560c) and to a drain of the first transistor 564a and a drain of the second transistor 564b as depicted in FIG. 5B. In general, a resistive matching stage 552 may utilize less area on an integrated circuit as compared to inductive matching networks.

The transconductance stage 554 includes a third transistor 570a and a fourth transistor 570b. The third and fourth transistors 570a and 570b are connected to form an inverter type architecture but other transconductance configurations can be likewise used. The third and fourth transistors 570a-b may be p-type and n-type MOSFETs respectively. The gates of the first transistor 564a and the third transistor 570a are coupled to the PMOS DC bias voltage, and the gates of the second transistor 564b and the fourth transistor 570b are coupled to the NMOS DC bias voltage. The drains of the third transistor 570a and the fourth transistor 570b are coupled to the load 558 via a capacitance element 572. Other AC coupling components are possible in other configurations. The transconductance stage 554 may include noise from the resistive matching stage that may be canceled when combined with the output from the current combiner 556 in an out of phase manner.

The current combiner 556 is operably coupled to the resistive matching stage 552 and the load 558. In an example, the current combiner 556 includes a n-type transistor 582, and an RC filter network including a second variable resistance element 584 and a variable capacitance element 586. The n-type transistor 582 may be referred to as the fifth transistor 582 in view of the first transistor 564a and the second transistor 564b. The RC filter is coupled to the source side of the fifth transistor 582 and can extend the noise cancellation features of the LNA 550 through a broad range of frequencies by changing the phase of the noise signal. Specifically, the fifth transistor 582 is configured to sample the output of the resistive matching stage 552 and inject the sampled signal into the load 558 with that of the transconductance stage 554. The second variable resistance element 584 and the variable capacitance element 586 may be respectively banks of resistors and capacitors that may be set based on the frequency band and used to control the phase of the injected signal. The current combiner 556 extends the noise cancellation capability over much wider range of frequencies by controlling the phase of the injected signal with the RC filter.

In an embodiment the noise cancelling LNA 550 includes a radio-frequency input (RF Vin)) and the first transistor 564a. A gate of the first transistor 564a is operably coupled to the radio-frequency input. The LNA 550 includes the second transistor 564b. A gate of the second transistor 564b is operably coupled to the radio-frequency input. The LNA 550 includes a first variable resistance element 562 including an input and an output, the input being operably coupled to the radio-frequency input, and the output being operably coupled to a drain of the first transistor 564a and a drain of the second transistor 564b. The LNA 550 includes a third transistor 570a. A gate of the third transistor 570a is operably coupled to the gate of the first transistor 564a. The LNA 550 includes a fourth transistor 570b. A gate of the fourth transistor 570b is operably coupled to the gate of the second transistor 564b. The LNA 550 includes a fifth transistor 582. A gate of the fifth transistor 582 is operably coupled to the output of the first variable resistance element 562, the drain of the first transistor 564a, and the drain of the second transistor 564b. The LNA 550 includes a second variable resistance element 584 including an input and an output, the input being operably coupled to a source of the fifth transistor 582, and the output being operably coupled to a drain of the third transistor 570a and a drain of the fourth transistor 570b. The LNA 550 includes a variable capacitance element 586 including an input and an output, the input being operably coupled to the input of the second variable resistance element 584, and the output being operably coupled to the output of the second variable resistance element 584. An output of the noise cancelling LNA 550 is operably coupled to the output of the variable capacitance element 586 and the drain of the third transistor 570a and the drain of the fourth transistor 570b.

In an aspect, as illustrated each of the transconductance stage 554 and the resistive matching stage include transistors based on an inverter architecture. However, other transconductance circuits may also be used such as single transistors, cascodes, or other non-CMOS transconductance architectures. Furthermore, the transconductance stage 554, while shown with just one inverter stage may include multiple stages (e.g., multiple inverters or other cascaded transconductance elements). The transconductance stage 554 may have a programmable/adjustable gain. Furthermore, any of the transconductance elements or transistors in the resistive matching stage 552 or the current combiner 556 may also be configured to have a programmable gain or include multiple cascaded elements. Moreover, as will be appreciated by those of skill, the components shown in FIG. 5B may have additional biases provided or include other intervening coupling elements (e.g., in addition to the AC coupling shown by the capacitance element 572). Note that the term ‘coupling’ in certain situations as appreciated by one with skill may refer to AC coupling techniques.

Based on the circuits shown in FIGS. 5A and 5B, an input signal at RF Vin goes through two parallel paths (e.g., through the transconductance stage 554 and coupling capacitance element 572 and through the resistive matching stage 552). The following description uses the reference numbers from FIG. 5B, but those of FIG. 5A may likewise be applied. Noise from the resistive matching stage 552 is fed through the transconductance stage 554 in an out-of-phase manner resulting noise cancellation (while the signals from the two paths are summed in-phase).

The transconductance stage 554 may form a noise cancellation path. The path through the resistive matching stage 552 may provide an impedance via the first variable resistance element 562 (e.g., tuned to create overall 50-ohm input impedance). The current combiner 556 is used to combine the gm of the path through resistive matching stage 552 and the gm of the path through the transconductance stage 554. Noise through the path of the resistive matching stage 552 is sampled at the input impedance and converted into current through the transconductance stage 554. Signals going through the parallel paths are then combined where the RF signal from each path is combined in-phase while the sampled noise is combined out-of-phase.

The current combiner 556 may sum the gm from the resistive matching stage 552 with the gm through the transconductance stage 554 using a source follower as illustrated by the arrangement of the fifth transistor 582 (other voltage-to-current converter architectures may also be used). As noted above, the RC elements 584 and 586 act as a phase shifter to tune the phases between the output of the transconductance stage 554 and the output of the resistive matching stage 552.

While certain transistors are noted as n-type or p-type it should be appreciated that these types may be reversed or configured in a way consistent with the disclosure but using different types or different transistor technologies.

Furthermore, while the first variable resistance element 562, the second variable resistance element 584 and the variable capacitance element 586 are shown variable/tunable elements, in some embodiments each of these elements may be fixed values. As such, the disclosure contemplates at least one embodiment where these elements have fixed values.

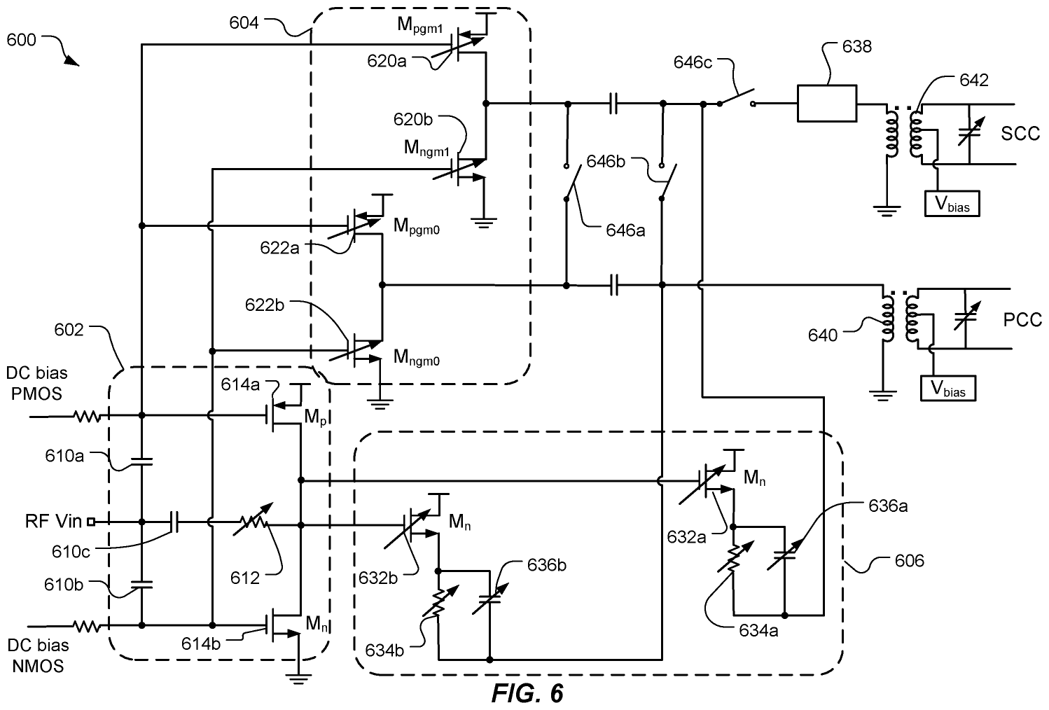

Referring to FIG. 6, a transistor level schematic diagram of a broadband intra-CA noise cancellation architecture 600 is shown. The architecture 600 extends the noise cancellation circuitry described in FIG. 5B to non-contiguous CA applications. The architecture includes a resistive matching stage 602, a transconductance stage 604 forming a cancellation path, and a current combiner 606. In this example, the transconductance stage 604 and the current combiner 606 include switches configured to enable multiple paths such as a PCC and at least one SCC. The concepts may also be extended to additional paths (not shown in FIG. 6). A communications signal input (RF Vin) and DC bias voltage are provided to the resistive matching stage 602. The resistive matching stage includes a plurality of DC blocking capacitors 610a-c, a first variable resistance element 612, a first transistor 614a, and a second transistor 614b. The first transistor 614a may be a p-type MOSFET and the second transistor 614b may be a n-type MOSFET. Other switching devices may also be used. The first variable resistance element 612 is coupled to the RF Vin signal (via the DC blocking capacitor 610c) and to the drains of the first and second transistors 614a-b as depicted in FIG. 6. The transconductance stage 604 is an example of a cancellation means and may include a plurality of cancellation paths. For example, a first transconductance stage may include two transistors 620a, 620b and a second transconductance stage may include two transistors 622a, 622a. The plurality of transconductance stages may be used for different components in a non-contiguous CA application. In an example, a primary component carrier path may include a first pcc transistor 622a (p-type) and a second pcc transistor 622b (n-type). A secondary component carrier path may include a first scc transistor 620a (p-type) and a second scc transistor 620b (n-type). The gates of the first transistor 614a, the first scc transistor 620a, and the first pcc transistor 622a are coupled to the PMOS DC bias voltage, and the gates of the second transistor 614b, the second scc transistor 620b, and the second pcc transistor 622b are coupled to the NMOS DC bias voltage.

The current combiner 606 may include a plurality of current combiner circuits that are operably coupled to the resistive matching stage 602. For example, a first current combiner circuit may include a first transistor 632a and first filter network 634a, 636a, and a second current combiner circuit may include a second transistor 632b and a second filter network 634b, 636b. The values of the RC components may be based on the frequencies of the PCC and SCC. The output of the current combiner circuits are operably coupled to a respective one of the primary and secondary carrier paths as depicted in FIG. 6. The architecture 600 includes a plurality of switches 646a-c configured to enable a first current flow and a second current flow as the respective primary and secondary component carriers. In an example, the switches 646a-c enable non-contiguous CA or legacy operation. For example, non-contiguous CA operation may be enabled when the switches are off and legacy operation may be enabled when the switches are in the on position. The PCC routing may utilized a first transformer 640 (e.g., a first load). The SCC a second transformer 642 (e.g., a second load). As one example, the broadband LNA architecture 600 may be configured to support frequencies in the range of 600 MHz to 3.8 GHz with intra-CA capability and includes noise cancellation features. Resistive matching is used via the resistive matching stage 602, with the noise generated in the resistive matching stage 602 cancelled through the cancellation path (e.g., through transconductance stage 604). The noise cancellation is provided over a wide range frequency by controlling phase of the current combiner 606 using tunable RC filter networks (e.g., phase shifter as source-follower design to enable current combining and achieve noise cancellation). Noise generated by matching circuitry may be cancelled in both the PCC and SCC intra-CA path.

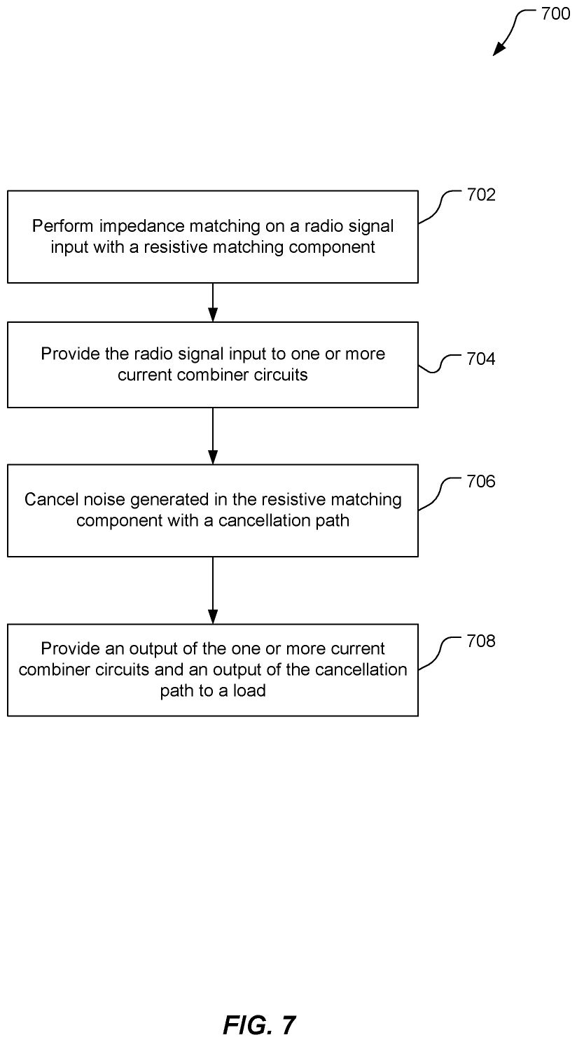

Referring to FIG. 7, with further reference to FIGS. 1-6, a method 700 of providing noise cancellation in a low noise amplifier (LNA) includes the stages shown. The method 700 is, however, an example only and not limiting. The method 700 may be altered, e.g., by having stages added, removed, rearranged, combined, performed concurrently, and/or having single stages split into multiple stages.

At stage 702, the method includes performing impedance matching on a radio signal input with a resistive matching stage. The resistive matching stage 602 receives an RF input and may include a first variable resistance element 612 and a plurality of transistors 614a-b. The value of the resistance may vary based on the frequency of the RF input. In a broadband application the value of the RF input may vary between 600 MHz to 3.8 GHz.

At stage 704, the method includes providing the radio signal input to one or more current combiner circuits. The resistive matching stage 602 is operably coupled to the current combiner 606. The current combiner 606 includes one or more transistors 632a-b and RC filter networks 634a-b, 636a-b. The values of the resistors and capacitors in the RC networks may vary based on the frequency of the RF input. The current combiner is configured to control the phase of the injected signal using the RC filter networks. The current combiner 606 may be configured to control the phase of both the PCC and SCC paths.

At stage 706, the method includes cancelling noise generated in the resistive matching stage. The transconductance stage 604 is operably coupled to the resistive matching stage 602 and includes a plurality of transistors 620a-b, 622a-b where noise generated on the PCC and SCC paths is canceled using out of phase combining. The resistive matching stage 602, including the transistors 614a-b, generates noise which may impact the performance of the LNA architecture.

At stage 708, the method includes providing an output of the current combiner 606 and an output of the transconductance stage 604 to a load. The load may be along the PCC or SCC path such as, for example, the first transformer 640 and the second transformer 642. The use of the current combiner 606 enables the control of the phase of the output signal for different frequencies. This phase control extends the operating frequency range of the cancellation circuit. The switching circuitry extends the frequency range performance to non-contiguous CA applications.

The LNA circuit described herein may be implemented on one or more ICs, analog ICs, RFICs, mixed-signal ICs, ASICs, printed circuit boards (PCBs), electronic devices, etc. The LNA circuit may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing the LNA circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

Other examples and implementations are within the scope and spirit of the disclosure and appended claims. For example, due to the nature of hardware, software and computers, functions described above can be implemented using software executed by a processor, hardware, firmware, hardwiring, or a combination of any of these. Features implementing functions may also be physically located at various positions, including being distributed such that portions of functions are implemented at different physical locations.

Also, as used herein, “or” as used in a list of items prefaced by “at least one of” or prefaced by “one or more of” indicates a disjunctive list such that, for example, a list of “at least one of A, B, or C,” or a list of “one or more of A, B, or C,” or “A, B, or C, or a combination thereof” means A or B or C or AB or AC or BC or ABC (i.e., A and B and C), or combinations with more than one feature (e.g., AA, AAB, ABBC, etc.).

As used herein, unless otherwise stated, a statement that a function or operation is “based on” an item or condition means that the function or operation is based on the stated item or condition and may be based on one or more items and/or conditions in addition to the stated item or condition.

Substantial variations may be made in accordance with specific requirements. For example, customized hardware might also be used, and/or particular elements might be implemented in hardware, software (including portable software, such as applets, etc.), or both.

The methods, systems, and devices discussed above are examples. Various configurations may omit, substitute, or add various procedures or components as appropriate. For instance, in alternative configurations, the methods may be performed in an order different from that described, and that various steps may be added, omitted, or combined. Also, features described with respect to certain configurations may be combined in various other configurations. Different aspects and elements of the configurations may be combined in a similar manner. Also, technology evolves and, thus, many of the elements are examples and do not limit the scope of the disclosure or claims.

Specific details are given in the description to provide a thorough understanding of example configurations (including implementations). However, configurations may be practiced without these specific details. For example, well-known circuits, processes, algorithms, structures, and techniques have been shown without unnecessary detail in order to avoid obscuring the configurations. This description provides example configurations only, and does not limit the scope, applicability, or configurations of the claims. Rather, the preceding description of the configurations provides a description for implementing described techniques. Various changes may be made in the function and arrangement of elements without departing from the spirit or scope of the disclosure.

Also, configurations may be described as a process which is depicted as a flow diagram or block diagram. Although each may describe the operations as a sequential process, some operations may be performed in parallel or concurrently. In addition, the order of the operations may be rearranged. A process may have additional stages or functions not included in the figure. Furthermore, examples of the methods may be implemented by hardware, software, firmware, middleware, microcode, hardware description languages, or any combination thereof When implemented in software, firmware, middleware, or microcode, the program code or code segments to perform the tasks may be stored in a non-transitory computer-readable medium such as a storage medium. Processors may perform one or more of the described tasks.

Components, functional or otherwise, shown in the figures and/or discussed herein as being connected, coupled (e.g., communicatively coupled), or communicating with each other are operably coupled. That is, they may be directly or indirectly, wired and/or wirelessly, connected to enable signal transmission between them.

Having described several example configurations, various modifications, alternative constructions, and equivalents may be used without departing from the spirit of the disclosure. For example, the above elements may be components of a larger system, wherein other rules may take precedence over or otherwise modify the application of the invention. Also, a number of operations may be undertaken before, during, or after the above elements are considered. Accordingly, the above description does not bound the scope of the claims.

“About” and/or “approximately” as used herein when referring to a measurable value such as an amount, a temporal duration, and the like, encompasses variations of ±20% or ±10%, ±5%, or +0.1% from the specified value, as appropriate in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or +0.1% from the specified value, as appropriate in the context of the systems, devices, circuits, methods, and other implementations described herein.

Further, more than one invention may be disclosed.

1. A noise cancellation circuit, comprising:
a first transconductance stage operably coupled to a radio-frequency input;
a resistive matching circuit comprising:
a second transconductance stage operably coupled to the radio-frequency input; and
a first resistance element having a first terminal operably coupled to the radio-frequency input and a second terminal operably coupled to an output of the second transconductance stage;
a voltage-to-current converter circuit having an input terminal operably coupled to the output of the second transconductance stage;
a second resistance element having a first terminal operably coupled to an output of the voltage-to-current converter circuit and a second terminal operably coupled to an output of the first transconductance stage; and
a capacitance element having a first terminal operably coupled to the output of the voltage-to-current converter circuit and a second terminal operably coupled to the output of the first transconductance stage.

2. The noise cancellation circuit of claim 1, wherein the first transconductance stage comprises a capacitor coupled between the second terminal of the second resistance element and one or more transconductance elements of the first transconductance stage.

3. The noise cancellation circuit of claim 1 wherein the first resistance element is a first variable resistance element.

4. The noise cancellation circuit of claim 1 wherein the second resistance element is a second variable resistance element or the capacitance element is a variable capacitance element.

5. The noise cancellation circuit of claim 1, wherein the second transconductance stage comprises:
a first transistor having a gate operably coupled to the radio-frequency input; and
a second transistor having a gate operably coupled to the radio-frequency input, wherein the second terminal of the first resistance element is operably coupled to a drain of the first transistor and a drain of the second transistor, wherein the first transconductance stage comprises:
a third transistor having a gate operably coupled to the radio-frequency input; and
a fourth transistor having a gate operably coupled to the radio-frequency input, wherein the voltage-to-current converter circuit includes a fifth transistor, wherein the gate of the fifth transistor is operably coupled to the drain of the first transistor and the drain of the second transistor.

6. The noise cancellation circuit of claim 5 wherein the capacitance element is a first capacitance element, the first transconductance stage further comprising:
a sixth transistor having a gate operably coupled to the radio-frequency input;
a seventh transistor having a gate operably coupled to the radio-frequency input, wherein the voltage-to-current converter circuit further comprises;
an eighth transistor having a gate operably coupled to the drain of the first transistor and the drain of the second transistor;
a third resistance element having a first terminal operably coupled to a source of the eighth transistor and a second terminal operably coupled to a drain of the sixth transistor and to a drain of the seventh transistor via a capacitor; and
a second capacitance element having a first terminal operably coupled to the source of the eighth transistor and a second terminal operably coupled to the drain of the sixth transistor and the drain of the seventh transistor via the capacitor.

7. The noise cancellation circuit of claim 6, wherein:
a primary component carrier processing circuit is coupled to a first node coupled to the drain of the third transistor, the drain of the fourth transistor, and the second terminals of each of the second resistance element and the first capacitance element; and
a secondary component carrier processing circuit is coupled to a second node coupled to the drain of the sixth transistor, the drain of the seventh transistor, and the second terminals of each of the third resistance element and the second capacitance element.

8. The noise cancellation circuit of claim 6 further comprising:
a first switch having a first terminal operably connected to the drain of the third transistor and the drain of the fourth transistor, the first switch having a second terminal operably coupled to the drain of the sixth transistor and the drain of the seventh transistor; and
a second switch in parallel with the first switch and having a first terminal operably connected to the drain of the third transistor and the drain of the fourth transistor, the first switch having a second terminal operably coupled to the drain of the sixth transistor and the drain of the seventh transistor.

9. The noise cancellation circuit of claim 1, wherein each of the first transconductance stage and the second transconductance stage comprise at least one of an inverter, a transistor, or a cascode.

10. The noise cancellation circuit of claim 1 wherein a value of the second resistance element and a value of the capacitance element is based on a frequency of a signal at the radio-frequency input.

11. The noise cancellation circuit of claim 1 wherein a frequency of a signal at the radio-frequency input is in a range of 600 MHz to 3.8 GHz.

12. The noise cancellation circuit of claim 1 wherein the noise cancellation circuit forms at least a portion of a low noise amplifier (LNA) circuit in a receive path of a transceiver.

13. The noise cancellation circuit of claim 1 wherein an output of the noise cancellation circuit is operably connected to a node operably coupled to the output of the second transconductance stage and the second terminals of each of the second resistance element and the capacitance element.

14. The noise cancellation circuit of claim 1 wherein the radio-frequency input includes a primary component carrier and a secondary component carrier in a carrier aggregation application.

15. The noise cancellation circuit of claim 14 wherein the primary component carrier and the secondary component carrier are based on a non-contiguous carrier aggregation application.

16. A device, comprising:
a resistive matching stage configured to receive a communication signal;
a first cancellation path configured to receive the communication signal, the first cancellation path operably coupled to the resistive matching stage and a first load; and
a first current combiner circuit operably coupled to the resistive matching stage and the first load, the first current combiner circuit being configured to control a phase of a current of the communication signal received from the resistive matching stage.

17. The device of claim 16, wherein the first current combiner circuit is controlled to cancel noise through the first cancellation path from the resistive matching stage.

18. The device of claim 17, wherein noise from the resistive matching stage through the first cancellation path is combined out-of-phase with noise through the resistive matching stage.

19. The device of claim 16 wherein:
the resistive matching stage includes a first variable resistance element operably coupled to a drain of a first transistor and a drain of a second transistor; and
the first cancellation path includes a third transistor and a fourth transistor, a gate of the third transistor being operably coupled to a gate of the first transistor in the resistive matching stage, and a gate of the fourth transistor being operably coupled to a gate of the second transistor in the resistive matching stage.

20. The device of claim 19 wherein the first current combiner circuit includes a fifth transistor and a filter network, a gate of the fifth transistor being operably coupled to the first variable resistance element in the resistive matching stage, and a source of the fifth transistor being operably coupled to a second variable resistance element and a variable capacitance element in the filter network.

21. The device of claim 20 wherein a value of the second variable resistance element and a value of the variable capacitance element is based on a frequency of the communication signal.

22. The device of claim 16 wherein the communication signal includes a primary component carrier and a secondary component carrier in a carrier aggregation application.

23. The device of claim 16 further comprising:
a second cancellation path operably coupled to the resistive matching stage and a second load; and
a second current combiner circuit operably coupled to the resistive matching stage and the second load.

24. The device of claim 19 further comprising:
a second cancellation path, wherein the second cancellation path includes a first secondary component carrier transistor and a second secondary component carrier transistor, a gate of the first secondary component carrier transistor being operably coupled to a gate of the first transistor in the resistive matching stage, and a gate of the second secondary component carrier transistor being operably coupled to a gate of the second transistor in the resistive matching stage;
a second current combiner circuit, wherein the second current combiner circuit includes a second current combiner transistor and a second current combiner filter network, a gate of the second current combiner transistor being operably coupled to the first variable resistance element in the resistive matching stage, and a source of the second transistor being operably coupled to the second current combiner filter network; and
the second current combiner filter network being operably coupled to a second load.

25. The device of claim 24 further comprising a plurality of switches configured to enable a first current flow from the first cancellation path and the first current combiner circuit to the first load, or to enable a second current flow from the second cancellation path and the second current combiner circuit to the second load.

26. The device of claim 16 wherein the device is at least a portion of a low noise amplifier (LNA) circuit in a receive path of a transceiver.

27. A method for providing noise cancellation, comprising:
performing impedance matching of a radio signal input with a resistive matching component;
providing the radio signal input to one or more current combiner circuits;
cancelling noise generated in the resistive matching component with a cancellation path; and
providing an output of the one or more current combiner circuits and an output of the cancellation path to a load.

28. The method of claim 27 further comprising setting a resistance value for at least one resistor and a capacitance value for at least one capacitor in the one or more current combiner circuits, wherein the resistance value and the capacitance value are based on a frequency of the radio signal input.

29. The method of claim 27 wherein the radio signal input includes a primary component carrier and a secondary component carrier.

30. A device, comprising:
a resistive matching means configured to receive communication signal;
means for canceling noise generated in the resistive matching means; and
means for controlling a phase of a current of the communication signal received from the resistive matching means.
